(19) United States
(12) Patent Application Publication
(10) Pub. No.: US 2018/0233687 A1
(43) Pub. Date: Aug. 16, 2018

(54) MATERIAL FOR ORGANIC ELECTROLUMINESCENT DEVICE AND ORGANIC ELECTROLUMINESCENT DEVICE USING SAME

(71) Applicant: NIPPON STEEL & SUMIKIN CHEMICAL CO., LTD., Tokyo (JP)

(72) Inventors: Takahiro Kai, Kitakyushu-shi, Fukuoka (JP); Hideki Tanaka, Kitakyushu-shi, Fukuoka (JP); Atsushi Kawada, Kitakyushu-shi, Fukuoka (JP)

(21) Appl. No.: 15/509,775

(22) PCT Filed: Aug. 18, 2015
(86) PCT No.: PCT/JP2015/073155

§ 371 Date: Mar. 8, 2017

(30) Foreign Application Priority Data
Sep. 29, 2014 (JP) 2014-198835

(51) Int. Cl. H01L 51/50; H01L 51/52; H01L 51/00

(52) U.S. Cl. CPC H01L 51/5024; H01L 51/5056; H01L 51/5072; H01L 51/5092; H01L 51/0074; H01L 51/5234; H01L 51/5206; H01L 51/5016; H01L 51/0072; H01L 51/5096

(57) ABSTRACT

Provided are a material for an organic electroluminescent device showing excellent electron- and hole-injecting/transporting properties, and having proper lowest singlet excitation energy and proper lowest triplet excitation energy, and an organic EL device using the material. The material for an organic electroluminescent device includes a heterocyclic compound represented by the general formula (1) where: R₁ represents an aromatic hydrocarbon group having 6 to 30 carbon atoms, an aromatic heterocyclic group having 3 to 22 carbon atoms, or a linked aromatic group obtained by linking 2 to 6 aromatic rings of the aromatic groups, an alkyl group, or an alkoxy group; R₂ to R₅ each represent an aromatic hydrocarbon group having 6 to 30 carbon atoms, an aromatic heterocyclic group having 3 to 22 carbon atoms, the group containing only oxygen or sulfur as a heteroatom, or a linked aromatic group obtained by linking 2 to 6 aromatic rings of the aromatic groups, an alkyl group, or an alkoxy group; and a, b, c, and d each represent an integer of from 0 to 2.

### TECHNICAL FIELD

The present invention relates to an organic electroluminescent device using a specific heterocyclic compound as a material for an organic electroluminescent device, and more specifically, to a thin film-type device that emits light by applying an electric field to a light-emitting layer containing an organic compound.

### BACKGROUND ART

In general, an organic electroluminescent device (hereinafter referred to as organic EL device) includes a light-emitting layer and a pair of counter electrodes interposing the light-emitting layer therebetween in its simplest structure. That is, the organic EL device uses the phenomenon that, when an electric field is applied between both the electrodes, electrons are injected from a cathode and holes are injected from an anode, and each electron and each hole recombine in the light-emitting layer to emit light.

In recent years, progress has been made in developing an organic EL device using an organic thin film. In order to enhance luminous efficiency particularly, the optimization of the kind of electrodes has been attempted for the purpose of improving the efficiency of injection of carriers from the electrodes. As a result, there has been developed a device in which a hole-transporting layer formed of an aromatic diamine and a light-emitting layer formed of an 8-hydroxyquinoline aluminum complex (Alq₃) are formed between electrodes as thin films, resulting in a significant improvement in luminous efficiency, as compared to related-art devices in which a single crystal of anthracene or the like is used. Thus, the development of the above-mentioned organic EL device has been promoted in order to accomplish its practical application to a high-performance flat panel having features such as self-luminescence and rapid response.

Further, investigations have been made on using phosphorescent light rather than fluorescent light as an attempt to raise the luminous efficiency of a device. Many kinds of devices including the above-mentioned device in which a hole-transporting layer formed of an aromatic diamine and a light-emitting layer formed of Alq₃ are formed emit light by using fluorescent light emission. However, by using phosphorescent light emission, that is, by using light emission from a triplet excited state, luminous efficiency is expected to be improved by from about three times to about four times, as compared to the case of using related-art devices in which fluorescent light (singlet) is used. In order to accomplish this purpose, investigations have been made on adopting a coumarin derivative or a benzophenone derivative as a light-emitting layer, but extremely low luminance has only been provided. Further, investigations have been made on using a europium complex as an attempt to use a triplet state, but highly efficient light emission has not been accomplished. In recent years, many investigations have been made mainly on an organic metal complex, for example, such an iridium complex as mentioned in Patent Literature 1, for the purpose of attaining high luminous efficiency and a long lifetime.

### CITATION LIST

### Patent Literature

[PTL 1] WO 01/041512 A1

[PTL 2] JP 2001-313178 A

[PTL 3] JP 2010-87408 A

[PTL 4] JP 2013-232521 A

In order to obtain high luminous efficiency, host materials that are used with the dopant materials described above play an important role. A typical example of the host materials proposed is 4,4′-bis(9-carbazolyl)biphenyl (CBP) as a carbazole compound disclosed in Patent Literature 2. When CBP is used as a host material for a green phosphorescent light-emitting material typifiedbyatris(2-phenylpyridine)iridiumcomplex (Ir(ppy)₃), the injection balance between charges is disturbed because of its characteristic of facilitating the delivery of holes and not facilitating the delivery of electrons. Thus, excessively delivered holes flow out into an electron-transporting layer side, with the result that the luminous efficiency from Ir(ppy)₃ lowers.

In order to provide high luminous efficiency to an organic EL device, it is necessary to use a host material that has high triplet excitation energy, and is striking a good balance in both charge (hole and electron)-injecting/transporting properties. Further desired is a compound that is electrochemically stable and has high heat resistance and excellent amorphous stability, and hence further improvement has been demanded.

In Patent Literature 3, there is a disclosure of a heterocyclic compound (H-1) represented by the following formula. However, the characteristics of the compound (H-1) are largely different from those of a compound to be used in the present invention because a bonding position in the basic skeleton of the compound (H-1) is different from that of the compound to be used in the present invention. In addition, in Patent Literature 3, there is a disclosure of the use of the compound (H-1) as an organic semiconductor layer for an organic transistor, but there is not a disclosure of the usefulness of the compound as an organic EL device material.

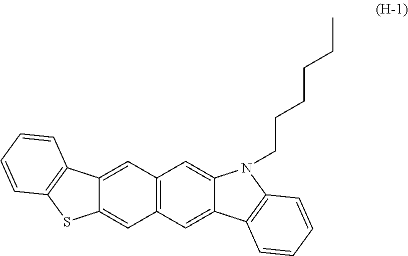 [SMILES: CCCCCCn1c2ccccc2c2cc3cc4sc5ccccc5c4cc3cc21]

In Patent Literature 4, there is a disclosure of a heterocyclic compound (H-2) represented by the following formula. The compound has the following structural feature: the compound has an amino group on a carbon atom of its basic skeleton directly or through a linking group. Accordingly, the compound involves a problem in that its transporting property for an electron and its stability deteriorate, and hence practically sufficient organic EL device characteristics are not obtained.

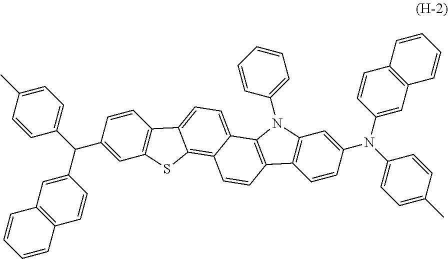

### SUMMARY OF INVENTION

In order to apply an organic EL device to a display device in a flat panel display or the like, it is necessary to improve the luminous efficiency of the device and also to ensure sufficiently the stability in driving the device. The present invention has an object to provide, in view of the above-mentioned circumstances, an organic EL device that has high efficiency and high driving stability and is practically useful and a compound suitable for the organic EL device.

The inventors of the present invention have made extensive investigations, and as a result, have found that when a specific heterocyclic compound is used in an organic EL device, the device shows excellent characteristics. Thus, the inventors have completed the present invention.

According to one embodiment of the present invention, there is provided a material for an organic electroluminescent device, including a heterocyclic compound represented by the general formula (1):

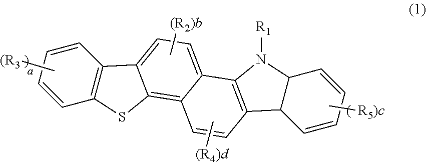

where: R₁ represents an alkyl group having 1 to 12 carbon atoms, an alkoxy group having 1 to 12 carbon atoms, a substituted or unsubstituted aromatic hydrocarbon group having 6 to 30 carbon atoms, a substituted or unsubstituted aromatic heterocyclic group having 3 to 22 carbon atoms, or a substituted or unsubstituted linked aromatic group obtained by linking 2 to 6 aromatic rings of the aromatic groups; R₂ to R₅ each independently represent an alkyl group having 1 to 12 carbon atoms, an alkoxy group having 1 to 12 carbon atoms, a substituted or unsubstituted aromatic hydrocarbon group having 6 to 30 carbon atoms, a substituted or unsubstituted aromatic heterocyclic group having 3 to 22 carbon atoms, the group containing only oxygen or sulfur as a heteroatom, or a substituted or unsubstituted linked aromatic group obtained by linking 2 to 6 aromatic rings of the aromatic groups; and a, b, c, and d each independently represent an integer of from 0 to 2.

According to another embodiment of the present invention, there is provided an organic electroluminescent device having a structure in which an anode, organic layers, and a cathode are laminated on a substrate, at least one layer of the organic layers including an organic layer containing the material for an organic electroluminescent device represented by the general formula (1).

It is preferred that the organic layer containing the material for an organic electroluminescent device include at least one layer selected from the group consisting of a light-emitting layer, an electron-transporting layer, and a hole-blocking layer, and it is more preferred that the organic layer containing the material for an organic electroluminescent device include a light-emitting layer.

In addition, when the organic layer containing the material for an organic electroluminescent device is the light-emitting layer, the light-emitting layer preferably contains a host material and a light-emitting dopant, and the material for an organic electroluminescent device is applicable as each of the host material and the light-emitting dopant. The light-emitting layer may contain two or more kinds of host materials, and may contain one or more kinds of light-emitting dopants. The material for an organic electroluminescent device is applicable as at least one kind of host material or light-emitting dopant.

When the material for an organic electroluminescent device is the host material, a phosphorescent light-emitting dopant, a fluorescent light-emitting dopant, or a delayed fluorescent light-emitting dopant is applicable as the light-emitting dopant.

In addition, when the material for an organic electroluminescent device is the light-emitting dopant, the material for an organic electroluminescent device is applicable as a fluorescent light-emitting dopant or a delayed fluorescent light-emitting dopant.

The material for an organic electroluminescent device of the present invention shows an excellent electron-injecting/transporting property and an excellent hole-injecting/transporting property. In addition, the material has proper lowest singlet excitation energy and proper lowest triplet excitation energy that affect its light-emitting characteristic. Accordingly, the use of the material in an organic EL device can achieve a reduction in driving voltage of the device and high luminous efficiency.

In addition, the material for an organic electroluminescent device shows a satisfactory amorphous characteristic, and high thermal stability and high electrical stability. Accordingly, an organic EL device using the material has a long driving life and durability at a practical level.

### BRIEF DESCRIPTION OF DRAWINGS

FIG. 1 is a sectional view for illustrating an example of the structure of an organic EL device.

### DESCRIPTION OF EMBODIMENTS

A material for an organic electroluminescent device of the present invention is a heterocyclic compound represented by the general formula (1).

In the general formula (1), R₁ represents an alkyl group having 1 to 12 carbon atoms, an alkoxy group having 1 to 12 carbon atoms, a substituted or unsubstituted aromatic hydrocarbon group having 6 to 30 carbon atoms, a substituted or unsubstituted aromatic heterocyclic group having 3 to 22 carbon atoms, or a substituted or unsubstituted linked aromatic group obtained by linking 2 to 6 aromatic rings of the aromatic groups (meaning aromatic rings of the substituted or unsubstituted aromatic hydrocarbon group having 6 to 30 carbon atoms, and the substituted or unsubstituted aromatic heterocyclic group having 3 to 22 carbon atoms), and preferably represents a substituted or unsubstituted aromatic hydrocarbon group having 6 to 22 carbon atoms, a substituted or unsubstituted aromatic heterocyclic group having 3 to 16 carbon atoms, or a substituted or unsubstituted linked aromatic group obtained by linking 2 to 6 aromatic rings of the aromatic groups. R₂ to R₅ each independently represent an alkyl group having 1 to 12 carbon atoms, an alkoxy group having 1 to 12 carbon atoms, a substituted or unsubstituted aromatic hydrocarbon group having 6 to 30 carbon atoms, a substituted or unsubstituted aromatic heterocyclic group having 3 to 22 carbon atoms, the group containing only oxygen or sulfur as a heteroatom, or a substituted or unsubstituted linked aromatic group obtained by linking 2 to 6 aromatic rings of the aromatic groups, and preferably represents an aromatic hydrocarbon group having 6 to 22 carbon atoms, a substituted or unsubstituted aromatic heterocyclic group having 3 to 16 carbon atoms, the group containing only oxygen or sulfur as a heteroatom, or a substituted or unsubstituted linked aromatic group obtained by linking 2 to 6 aromatic rings of the aromatic groups. a, b, c, and d each independently represent an integer of from 0 to 2.

In the description of R₁ to R₅, specific examples of the unsubstituted aromatic hydrocarbon group include groups each produced by removing hydrogen from an aromatic hydrocarbon compound, such as benzene, naphthalene, fluorene, anthracene, phenanthrene, triphenylene, tetraphenylene, fluoranthene, pyrene, or chrysene. Of those, a group produced by removing a hydrogen atom from benzene, naphthalene, fluorene, phenanthrene, or triphenylene is preferred.

Specific examples of the unsubstituted aromatic heterocyclic group include groups each produced by removing hydrogen from an aromatic heterocyclic compound, such as pyridine, pyrimidine, triazine, quinoline, isoquinoline, quinoxaline, quinazoline, naphthyridine, carbazole, acridine, azepine, tribenzazepine, phenazine, phenoxazine, phenothiazine, dibenzophosphole, dibenzoborole, dibenzofuran, dibenzothiophene, dibenzodioxine, or thianthrene. Of those, a group produced by removing a hydrogen atom from pyridine, pyrimidine, triazine, carbazole, dibenzofuran, or dibenzothiophene is preferred. However, in the case of each of R₂ to R₅, the group is a group produced by removing hydrogen from an aromatic heterocyclic compound containing only oxygen or sulfur as a heteroatom out of the aromatic heterocyclic compounds, and a group produced from an aromatic heterocyclic compound containing, as a heteroatom constituting a heterocycle, an atom except oxygen or sulfur is excluded.

The unsubstituted linked aromatic group is a linked aromatic group produced by removing hydrogen from an aromatic compound in which a plurality of aromatic rings of an aromatic hydrocarbon compound or an aromatic heterocyclic compound described in the unsubstituted aromatic hydrocarbon group and the unsubstituted aromatic heterocyclic group are linked to each other through a single bond. The linked aromatic group is a group formed by linking 2 to 6 aromatic rings, and the aromatic rings to be linked may be identical to or different from each other, and may include both an aromatic hydrocarbon group and an aromatic heterocyclic group. The number of the aromatic rings to be linked is preferably from 2 to 4, more preferably 2 or 3.

Here, the linked aromatic group is represented by, for example, any one of the following formulae.

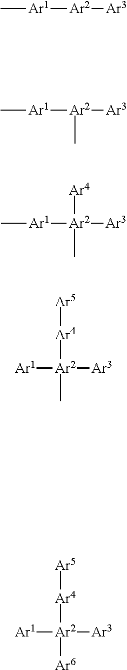

(Ar¹ to Ar⁶ each represent a substituted or unsubstituted aromatic ring.)

Specific examples of the linked aromatic group include groups each produced by removing hydrogen from biphenyl, terphenyl, phenylnaphthalene, diphenylnaphthalene, phenylanthracene, diphenylanthracene, diphenylfluorene, bipyridine, bipyrimidine, bitriazine, biscarbazole, phenylpyridine, phenylpyrimidine, phenyltriazine, phenylcarbazole, diphenylpyridine, diphenyltriazine, bis(carbazolyl)benzene, phenyldibenzofuran, phenyldibenzothiophene, or the like.

The aromatic hydrocarbon group, the aromatic heterocyclic group, or the linked aromatic group may have a substituent. When any such group has a substituent, the substituent is preferably an alkyl group having 1 to 12 carbon atoms, an alkoxy group having 1 to 12 carbon atoms, or an acyl group having 2 to 13 carbon atoms. The substituent is more preferably an alkyl group having 1 to 4 carbon atoms, an alkoxy group having 1 or 2 carbon atoms, or an acetyl group.

In the general formula (1), a, b, c, and d each represent an integer of from 0 to 2. (a+b+c+d) is an integer of preferably from 0 to 4, more preferably from 0 to 2.

The heterocyclic compound represented by the general formula (1) may be synthesized by, for example, such a method as represented by the following reaction formulae.

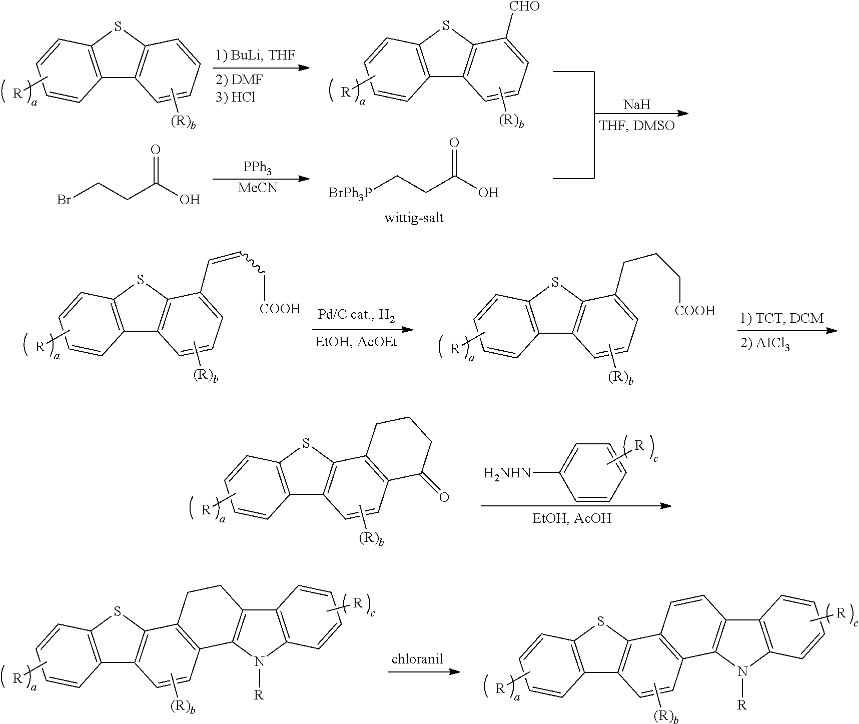

That is, a compound obtained by turning unsubstituted dibenzothiophene or dibenzothiophene having a substituent into an aldehyde and a Wittig-salt are caused to act on each other to synthesize a compound in which cyclohexanone is fused with dibenzothiophene. Further, the compound is caused to react with unsubstituted or substituted phenylhydrazine hydrochloride, followed by a dehydrogenation reaction. Thus, the aromatic heterocyclic compound represented by the general formula (1) may be synthesized.

Specific examples of the heterocyclic compound represented by the general formula (1) are shown below. However, the material for an organic electroluminescent device of the present invention is not limited thereto.

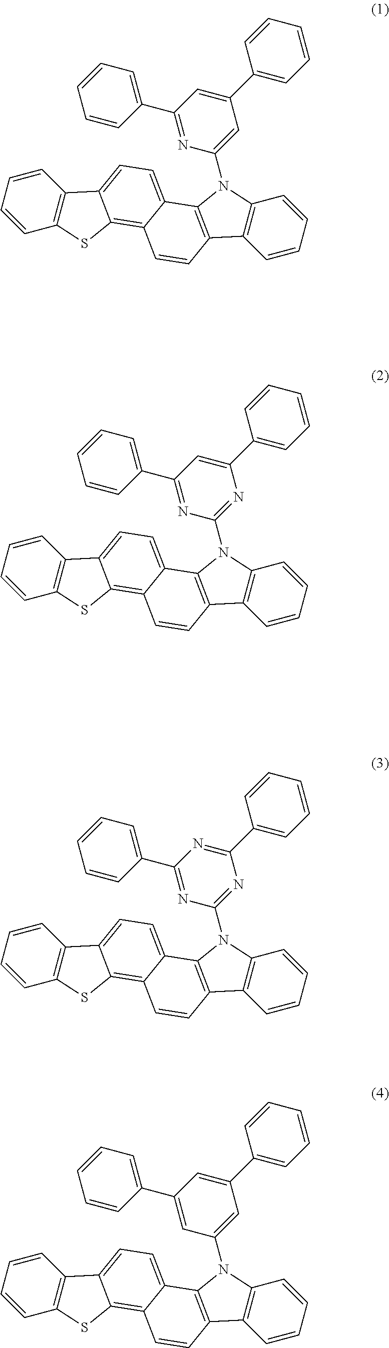

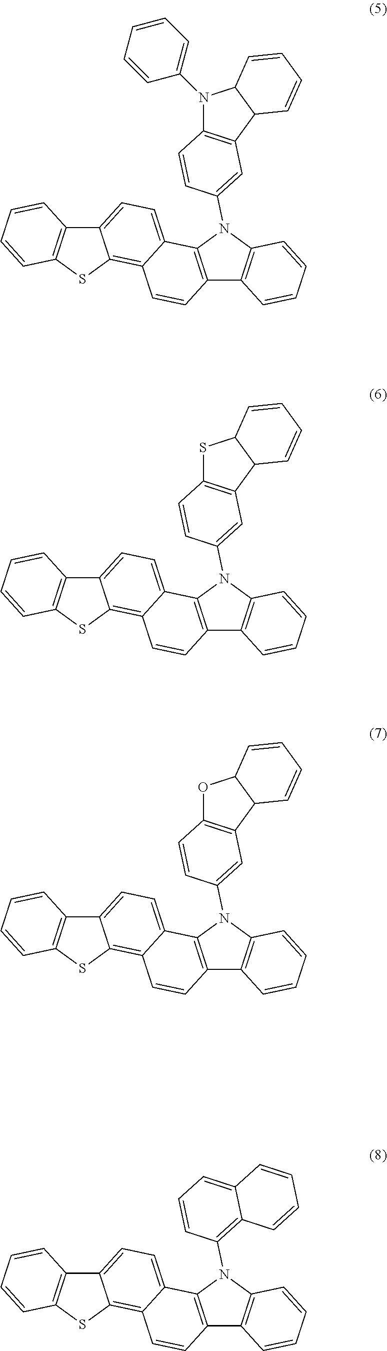

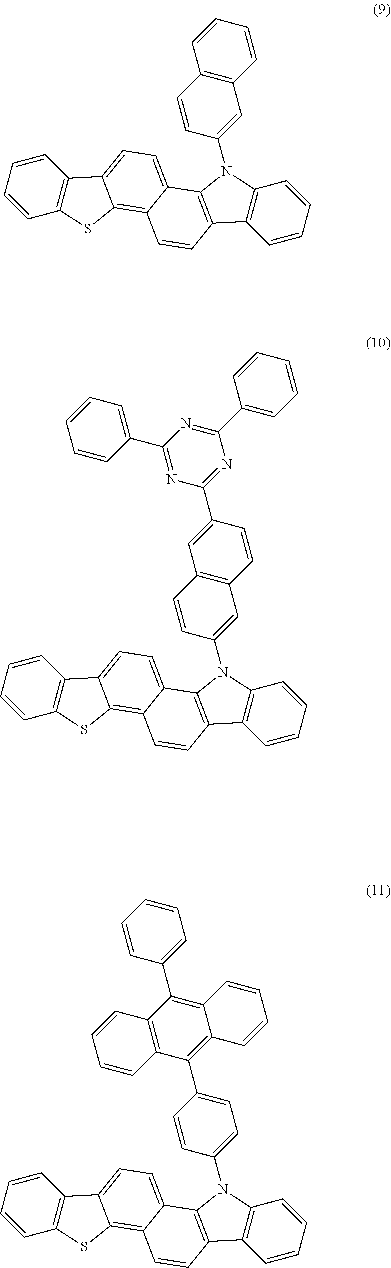

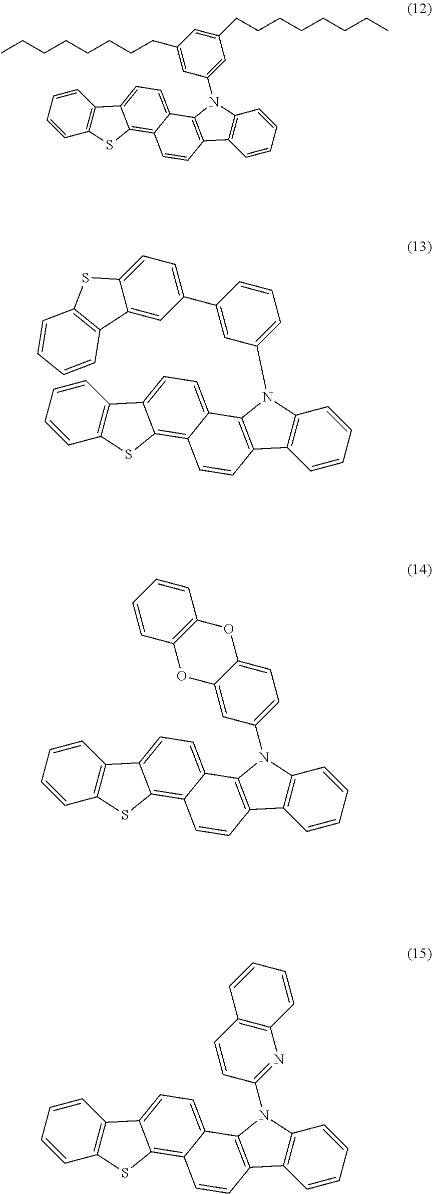

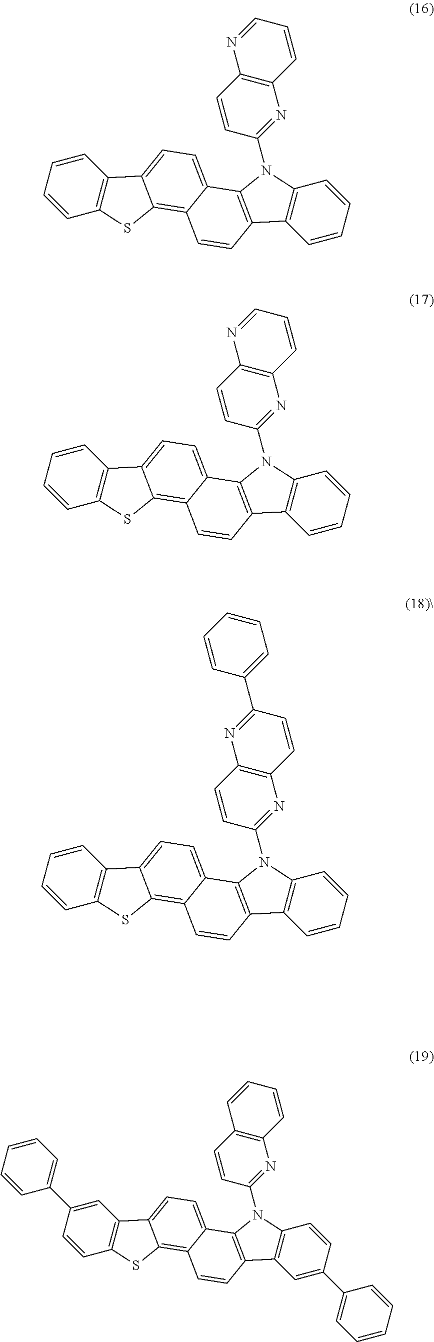

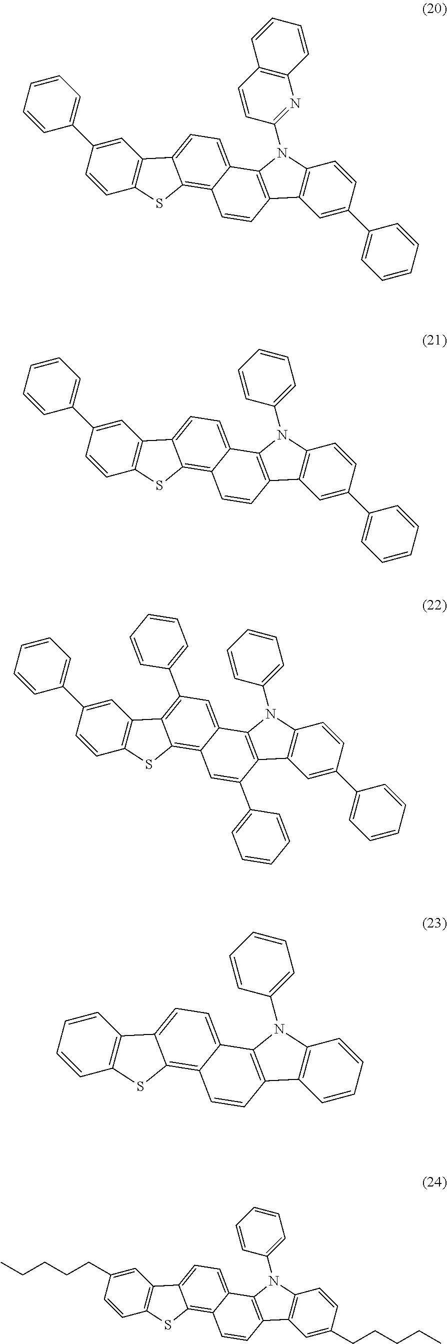

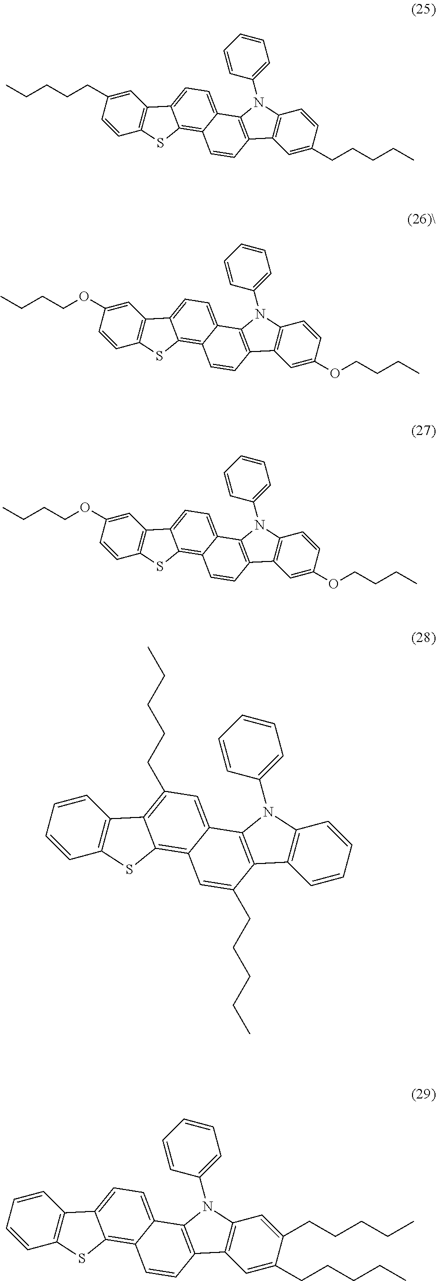

The material for an organic electroluminescent device of the present invention is formed of the heterocyclic compound represented by the general formula (1). When the material for an organic electroluminescent device of the present invention is contained in at least one of a plurality of organic layers of an organic EL device having a structure in which an anode, the plurality of organic layers, and a cathode are laminated on a substrate, an excellent organic electroluminescent device is provided. A light-emitting layer, an electron-transporting layer, or a hole-blocking layer is suitable as the organic layer in which the material is contained. Here, when the material for an organic electroluminescent device of the present invention is used in the light-emitting layer, the compound may be used as a host material for the light-emitting layer containing a fluorescent light-emitting, delayed fluorescent light-emitting, or phosphorescent light-emitting dopant. In addition, the material for an organic electroluminescent device of the present invention may be used as an organic light-emitting material that radiates fluorescence and delayed fluorescence. When the material for an organic electroluminescent device of the present invention is used as an organic light-emitting material that radiates fluorescence and delayed fluorescence, any other organic compound having a value for at least one of excited singlet energy or excited triplet energy higher than that of the material is preferably used as the host material. The material for an organic electroluminescent device of the present invention is particularly preferably incorporated as a host material for the light-emitting layer containing the phosphorescent light-emitting dopant.

Next, an organic EL device using the material for an organic electroluminescent device of the present invention is described.

The organic EL device of the present invention includes organic layers including at least one light-emitting layer between an anode and a cathode laminated on a substrate. In addition, at least one of the organic layers contains the material for an organic electroluminescent device of the present invention. The material for an organic electroluminescent device of the present invention is advantageously contained in the light-emitting layer together with a phosphorescent light-emitting dopant.

Next, the structure of the organic EL device of the present invention is described with reference to the drawings. However, the structure of the organic EL device of the present invention is by no means limited to one illustrated in the drawings.

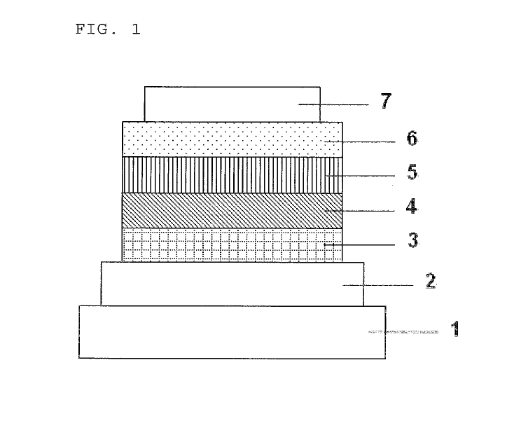

FIG. 1 is a sectional view for illustrating an example of the structure of a general organic EL device used in the present invention. Reference numeral 1 represents a substrate, reference numeral 2 represents an anode, reference numeral 3 represents a hole-injecting layer, reference numeral 4 represents a hole-transporting layer, reference numeral 5 represents a light-emitting layer, reference numeral 6 represents an electron-transporting layer, and reference numeral 7 represents a cathode. The organic EL device of the present invention may include an exciton-blocking layer adjacent to the light-emitting layer, or may include an electron-blocking layer between the light-emitting layer and the hole-injecting layer. The exciton-blocking layer may be inserted on any of the anode side and the cathode side of the light-emitting layer, and may also be inserted simultaneously on both sides. The organic EL device of the present invention includes the substrate, the anode, the light-emitting layer, and the cathode as its essential layers. The organic EL device of the present invention preferably includes a hole-injecting/transporting layer and an electron-injecting/transporting layer in addition to the essential layers, and more preferably includes a hole-blocking layer between the light-emitting layer and the electron-injecting/transporting layer. The hole-injecting/transporting layer means any one or both of the hole-injecting layer and the hole-transporting layer, and the electron-injecting/transporting layer means any one or both of an electron-injecting layer and the electron-transporting layer.

It is possible to adopt a reverse structure as compared to FIG. 1, that is, the reverse structure being formed by laminating the layers on the substrate 1 in the order of the cathode 7, the electron-transporting layer 6, the light-emitting layer 5, the hole-transporting layer 4, and the anode 2. In this case as well, some layers may be added or eliminated as required.

—Substrate—

The organic EL device of the present invention is preferably supported by a substrate. The substrate is not particularly limited, and any substrate that has long been conventionally used for an organic EL device may be used. For example, a substrate made of glass, a transparent plastic, quartz, or the like may be used.

—Anode—

Preferably used as the anode in the organic EL device is an anode formed by using, as an electrode substance, any of a metal, an alloy, an electrically conductive compound, and a mixture thereof, all of which have a large work function (4 eV or more). Specific examples of such electrode substance include metals such as Au and conductive transparent materials, such as CuI, indium tin oxide (ITO), SnO₂, and ZnO. In addition, a material such as IDIXO (In₂O₃—ZnO), which can produce an amorphous, transparent conductive film, may be used. In order to produce the anode, it may be possible to form any of those electrode substances into a thin film by using a method such as vapor deposition or sputtering and form a pattern having a desired shape thereon by photolithography. Alternatively, in the case of not requiring high pattern accuracy (about 100 μm or more), a pattern may be formed via a mask having a desired shape when any of the above-mentioned electrode substances is subjected to vapor deposition or sputtering. Alternatively, when a coatable substance, such as an organic conductive compound, is used, a wet film-forming method, such as a printing method or a coating method, may be used. When luminescence is taken out from the anode, the transmittance of the anode is desirably controlled to more than 10%. In addition, the sheet resistance of the anode is preferably several hundred ohms per square (Ω/□) or less. Further, the thickness of the film is, depending on its material, selected from the range of generally from 10 nm to 1,000 nm, preferably from 10 nm to 200 nm.

—Cathode—

Meanwhile, used as the cathode is a cathode formed by using, as an electrode substance, any of a metal (referred to as electron-injecting metal), an alloy, an electrically conductive compound, and a mixture thereof, all of which have a small work function (4 eV or less). Specific examples of such electrode substance include sodium, a sodium-potassium alloy, magnesium, lithium, a magnesium/copper mixture, a magnesium/silver mixture, a magnesium/aluminum mixture, a magnesium/indium mixture, an aluminum/aluminum oxide (Al₂O₃) mixture, indium, a lithium/aluminum mixture, and a rare earth metal. Of those, for example, a mixture of an electron-injecting metal and a second metal, which is a stable metal having a larger work function value than the former metal, such as a magnesium/silver mixture, a magnesium/aluminum mixture, a magnesium/indium mixture, an aluminum/aluminum oxide (Al₂O₃) mixture, or a lithium/aluminum mixture, or aluminum, is suitable from the viewpoints of an electron-injecting property and durability against oxidation or the like. The cathode may be produced by forming any of those electrode substances into a thin film by using a method such as vapor deposition or sputtering. In addition, the sheet resistance of the cathode is preferably several hundred Ω/□ or less, and the thickness of the film is selected from the range of generally from 10 nm to 5 μm, preferably from 50 nm to 200 nm. In order for luminescence produced to pass through, any one of the anode and cathode of the organic EL device is preferably transparent or semi-transparent, because the light emission luminance improves.

In addition, after the above-mentioned metal has been formed into a film having a predetermined thickness as a cathode, the conductive transparent material mentioned in the description of the anode is formed into a film on the cathode, thereby being able to produce a transparent or semi-transparent cathode. Through the application of this, a device in which both the anode and cathode have transparency can be produced.

—Light-Emitting Layer—

The light-emitting layer is a layer that emits light after the production of an exciton by the recombination of a hole injected from the anode and an electron injected from the cathode, and the light-emitting layer preferably contains an organic light-emitting material and a host material. Examples of the organic light-emitting material (light-emitting dopant) include a fluorescent light-emitting material (fluorescent light-emitting dopant), a phosphorescent light-emitting material (phosphorescent light-emitting dopant), and a delayed fluorescent light-emitting material (delayed fluorescent light-emitting dopant).

When the light-emitting layer is a fluorescent light-emitting layer, at least one kind of fluorescent light-emitting material may be used alone as the fluorescent light-emitting material. However, it is preferred that the fluorescent light-emitting material be used as a fluorescent light-emitting dopant and the host material be contained.

The material for an organic EL device of the present invention (sometimes referred to as heterocyclic compound of the present invention) may be used as the fluorescent light-emitting material. However, the fluorescent light-emitting material is known through, for example, many patent literatures, and hence may be selected therefrom. Examples thereof include a benzoxazole derivative, a benzothiazole derivative, a benzimidazole derivative, a styrylbenzene derivative, a polyphenyl derivative, a diphenylbutadiene derivative, a tetraphenylbutadiene derivative, a naphthalimide derivative, a coumarin derivative, a fused aromatic compound, a perinone derivative, an oxadiazole derivative, an oxazine derivative, an aldazine derivative, a pyrrolidine derivative, a cyclopentadiene derivative, a bisstyrylanthracene derivative, a quinacridone derivative, a pyrrolopyridine derivative, a thiadiazolopyridine derivative, a styrylamine derivative, a diketopyrrolopyrrole derivative, an aromatic dimethylidene compound, various metal complexes typified by a metal complex of an 8-quinolinol derivative, and a metal complex, rare earth complex, or transition metal complex of a pyrromethene derivative, polymer compounds, such as polythiophene, polyphenylene, and polyphenylene vinylene, and an organic silane derivative. Of those, for example, the following compound is preferred: a fused aromatic compound, a styryl compound, a diketopyrrolopyrrole compound, an oxazine compound, or a pyrromethene metal complex, transition metal complex, or lanthanoid complex. For example, the following compound is more preferred: naphthacene, pyrene, chrysene, triphenylene, benzo[c]phenanthrene, benzo[a]anthracene, pentacene, perylene, fluoranthene, acenaphthofluoranthene, dibenzo[a,j]anthracene, dibenzo[a,h]anthracene, benzo[a]naphthacene, hexacene, anthanthrene, naphtho[2,1-f]isoquinoline, α-naphthaphenanthridine, phenanthroxazole, quinolino[6,5-f]quinoline, or benzothiophanthrene. Those compounds may each have an alkyl group, an aryl group, an aromatic heterocyclic group, or a diarylamino group as a substituent.

The heterocyclic compound of the present invention may be used as a fluorescent host material. However, the fluorescent host material is known through, for example, many patent literatures, and hence may be selected therefrom. For example, the following material may be used: a compound having a fused aryl ring, such as naphthalene, anthracene, phenanthrene, pyrene, chrysene, naphthacene, triphenylene, perylene, fluoranthene, fluorene, or indene, or a derivative thereof; an aromatic amine derivative, such as N,N′-dinaphthyl-N,N′-diphenyl-4,4′-diphenyl-1,1′-diamine; a metal chelated oxinoid compound typified by tris(8-quinolinato)aluminum(III); a bisstyryl derivative, such as a distyrylbenzene derivative; a tetraphenylbutadiene derivative; an indene derivative; a coumarin derivative; an oxadiazole derivative; a pyrrolopyridine derivative; a perinone derivative; a cyclopentadiene derivative; a pyrrolopyrrole derivative; a thiadiazolopyridine derivative; a dibenzofuran derivative; a carbazole derivative; a dicarbazole derivative; an indolocarbazole derivative; a triazine derivative; or a polymer-based derivative, such as a polyphenylene vinylene derivative, a poly-p-phenylene derivative, a polyfluorene derivative, a polyvinyl carbazole derivative, or a polythiophene derivative. However, the fluorescent host material is not particularly limited thereto.

When the fluorescent light-emitting material is used as a fluorescent light-emitting dopant and the host material is contained, the content of the fluorescent light-emitting dopant in the light-emitting layer desirably falls within the range of from 0.01 wt % to 20 wt %, preferably from 0.1 wt % to 10 wt %.

An organic EL device typically injects charges from both of its electrodes, i.e., its anode and cathode into a light-emitting substance to produce a light-emitting substance in an excited state, and causes the substance to emit light. In the case of a charge injection-type organic EL device, it is said that 25% of the produced excitons are excited to a singlet excited state and the remaining 75% of the excitons are excited to a triplet excited state. As disclosed in Advanced Materials 2009, 21, 4802-4806, it has been known that after a specific fluorescent light-emitting substance has undergone an energy transition to a triplet excited state as a result of intersystem crossing or the like, the substance is subjected to inverse intersystem crossing to a singlet excited state by triplet-triplet annihilation or the absorption of thermal energy to radiate fluorescence, thereby expressing thermally activated delayed fluorescence. The organic EL device of the present invention can also express delayed fluorescence. In this case, the light emission may include both fluorescent light emission and delayed fluorescent light emission. Light emission from the host material may be present in part of the light emission.

When the light-emitting layer is a delayed fluorescent light-emitting layer, at least one kind of delayed fluorescent light-emitting material may be used alone as a delayed fluorescent light-emitting material. However, it is preferred that the delayed fluorescent light-emitting material be used as a delayed fluorescent light-emitting dopant and the host material be contained.

The heterocyclic compound of the present invention may be used as the delayed fluorescent light-emitting material. However, a material selected from known delayed fluorescent light-emitting materials may also be used. Examples thereof include a tin complex, an indolocarbazole derivative, a copper complex, and a carbazole derivative. Specific examples thereof include, but not limited to, compounds disclosed in the following non patent literatures and patent literature.

(1) Adv. Mater. 2009, 21, 4802-4806, (2) Appl. Phys. Lett. 98, 083302 (2011), (3) JP 2011-213643 A, and (4) J. Am. Chem. Soc. 2012, 134, 14706-14709.

Specific examples of the delayed fluorescent light-emitting material are shown below, but the delayed fluorescent light-emitting material is not limited to the following compounds.

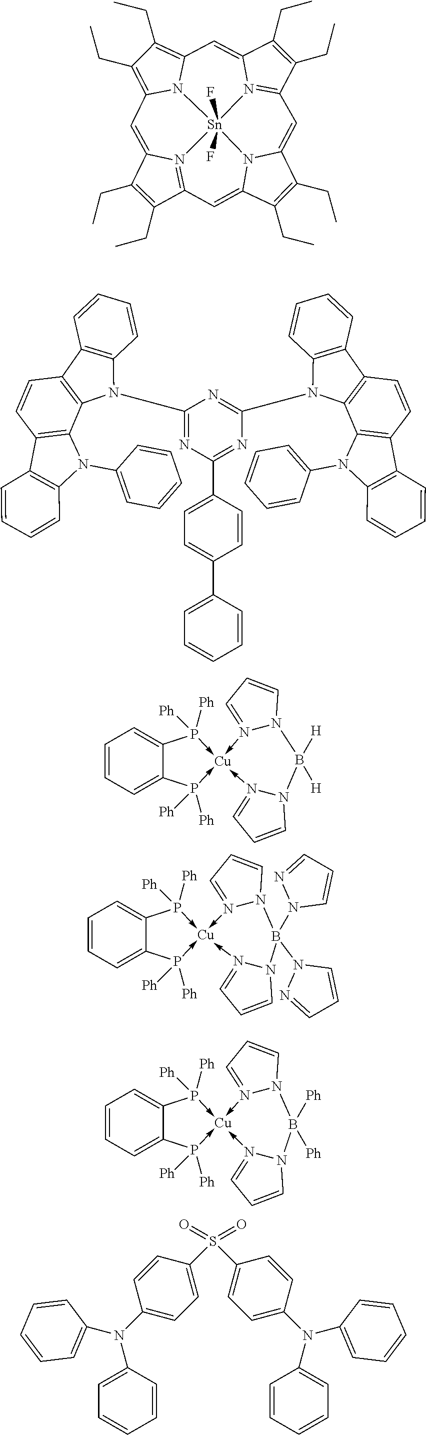

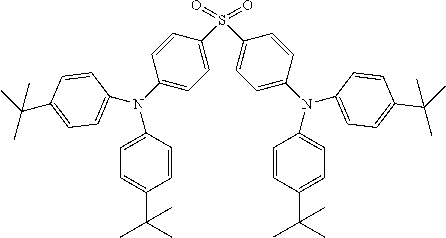 [SMILES: CC(C)(C)c1ccc(N(c2ccc(C(C)(C)C)cc2)c2ccc(S(=O)(=O)c3ccc(N(c4ccc(C(C)(C)C)cc4)c4ccc(C(C)(C)C)cc4)cc3)cc2)cc1]

When the delayed fluorescent light-emitting material is used as a delayed fluorescent light-emitting dopant and the host material is contained, the content of the delayed fluorescent light-emitting dopant in the light-emitting layer desirably falls within the range of from 0.01 wt % to 50 wt %, preferably from 0.1 wt % to 20 wt %, more preferably from 0.01 wt % to 10 wt %.

The heterocyclic compound of the present invention may be used as the delayed fluorescent host material. However, the delayed fluorescent host material may also be selected from compounds except the heterocyclic compound of the present invention. For example, the following compound may be used: a compound having a fused aryl ring, such as naphthalene, anthracene, phenanthrene, pyrene, chrysene, naphthacene, triphenylene, perylene, fluoranthene, fluorene, or indene, or a derivative thereof; an aromatic amine derivative, such as N,N′-dinaphthyl-N,N′-diphenyl-4,4′-diphenyl-1,1′-diamine; a metal chelated oxinoid compound typified by tris(8-quinolinato)aluminum(III); a bisstyryi derivative, such as a distyrylbenzene derivative; a tetraphenylbutadiene derivative; an indene derivative; a coumarin derivative; an oxadiazole derivative; a pyrrolopyridine derivative; a perinone derivative; a cyclopentadiene derivative; a pyrrolopyrrole derivative; a thiadiazolopyridine derivative; a dibenzofuran derivative; a carbazole derivative; a dicarbazole derivative; an indolocarbazole derivative; a triazine derivative; or a polymer-based derivative, such as a polyphenylene vinylene derivative, a poly-p-phenylene derivative, a polyfluorene derivative, a polyvinyl carbazole derivative, apolythiophene derivative, or an arylsilane derivative. However, the delayed fluorescent host material is not particularly limited thereto.

When the light-emitting layer is a phosphorescent light-emitting layer, the light-emitting layer contains a phosphorescent light-emitting dopant and a host material. It is recommended to use, as a material for the phosphorescent light-emitting dopant, a material containing an organic metal complex including at least one metal selected from ruthenium, rhodium, palladium, silver, rhenium, osmium, iridium, platinum, and gold.

Preferred examples of the phosphorescent light-emitting dopant include complexes such as Ir(ppy)₃ complexes such as Ir(bt)₂.acac₃, and complexes such as PtOEt₃, the complexes each having a noble metal element, such as Ir, as a central metal. Specific examples of those complexes are shown below, but the complexes are not limited to the following compounds.

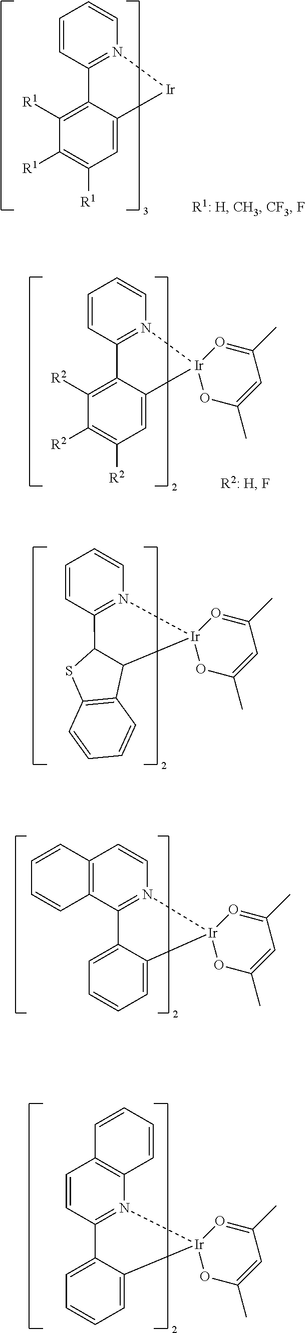

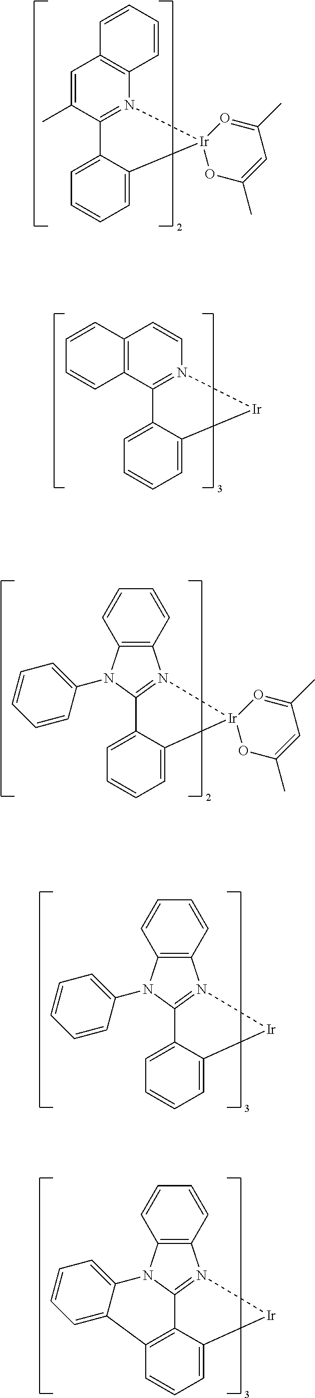

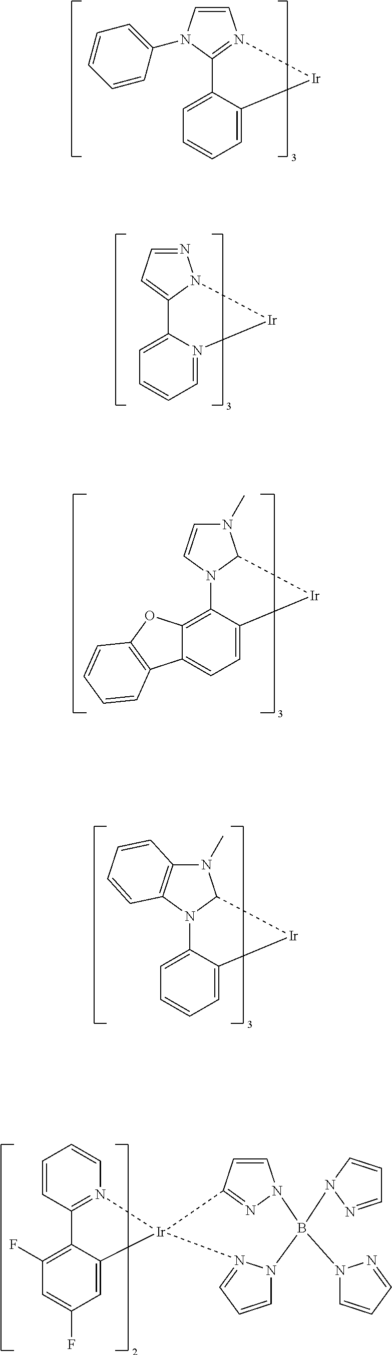

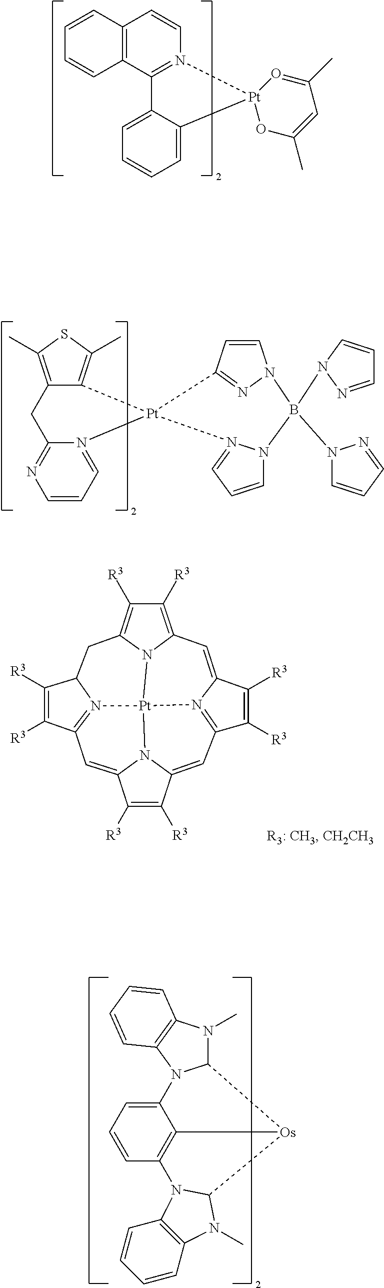

It is desired that the content of the phosphorescent light-emitting dopant in the light-emitting layer fall within the range of from 2 wt % to 40 wt %, preferably from 3 wt % to 20 wt %.

When the light-emitting layer is a phosphorescent light-emitting layer, it is preferred to use, as a host material in the light-emitting layer, the heterocyclic compound of the present invention. However, when the heterocyclic compound of the present invention is used in any other organic layer except the light-emitting layer, the material to be used in the light-emitting layer may be any other host material. In addition, the heterocyclic compound of the present invention may be used in combination with any other host material. Further, a plurality of kinds of known host materials may be used in combination.

It is preferred to use, as a known host compound that may be used, a compound that has a hole-transporting ability or an electron-transporting ability, is capable of preventing luminescence from having a longer wavelength, and has a high glass transition temperature.

Any such other host material is known through, for example, many patent literatures, and hence may be selected therefrom. Specific examples of the host material include, but not particularly limited to, aromatic compounds, such as an indole derivative, a carbazole derivative, a dicarbazole derivative, an indolocarbazole derivative, a triazole derivative, an oxazole derivative, an oxadiazole derivative, an imidazole derivative, a polyarylalkane derivative, a pyrazoline derivative, a pyrazolone derivative, a phenylenediamine derivative, an arylamine derivative, an amino-substituted chalcone derivative, a styrylanthracene derivative, a fluorenone derivative, a hydrazone derivative, a stilbene derivative, a silazane derivative, an aromatic tertiary amine compound, a styrylamine compound, an aromatic dimethylidene-based compound, a porphyrin-based compound, an anthraquinodimethane derivative, an anthrone derivative, a diphenylquinone derivative, a thiopyran dioxide derivative, and naphthalene perylene, various metal complexes typified by metal complexes of a phthalocyanine derivative, an 8-quinolinol derivative, a metal phthalocyanine derivative, a benzoxazole derivative, and a benzothiazole derivative, and polymer compounds, such as a polysilane-based compound, a poly(N-vinylcarbazole) derivative, an aniline-based copolymer, a thiophene oligomer, a polythiophene derivative, a polyphenylene derivative, a polyphenylenevinylene derivative, and a polyfluorene derivative.

The light-emitting layer, which may be any one of a fluorescent light-emitting layer, a delayed fluorescent light-emitting layer, and a phosphorescent light-emitting layer, is preferably the phosphorescent light-emitting layer.

—Injecting Layer—

The injecting layer refers to a layer formed between an electrode and an organic layer for the purposes of lowering a driving voltage and improving light emission luminance, and includes a hole-injecting layer and an electron-injecting layer. The injecting layer may be interposed between the anode and the light-emitting layer or the hole-transporting layer, or may be interposed between the cathode and the light-emitting layer or the electron-transporting layer. The injecting layer may be formed as required.

—Hole-Blocking Layer—

The hole-blocking layer has, in a broad sense, the function of an electron-transporting layer, and is formed of a hole-blocking material that has a remarkably small ability to transport holes while having a function of transporting electrons, and hence the hole-blocking layer is capable of improving the probability of recombining an electron and a hole by blocking holes while transporting electrons.

It is preferred to use the heterocyclic compound of the present invention for the hole-blocking layer. However, when the heterocyclic compound is used in any other organic layer, a known material for a hole-blocking layer may be used. In addition, a material for the electron-transporting layer to be described later may be used as a material for the hole-blocking layer as required.

—Electron-Blocking Layer—

The electron-blocking layer is formed of a material that has a remarkably small ability to transport electrons while having a function of transporting holes, and hence the electron-blocking layer is capable of improving the probability of recombining an electron and a hole by blocking electrons while transporting holes

A material for the hole-transporting layer to be described later may be used as a material for the electron-blocking layer as required. The thickness of the electron-blocking layer is preferably from 3 nm to 100 nm, more preferably from 5 nm to 30 nm.

—Exciton-Blocking Layer—

The exciton-blocking layer refers to a layer for blocking excitons produced by the recombination of a hole and an electron in the light-emitting layer from diffusing into charge-transporting layers. The insertion of the exciton-blocking layer enables efficient confinement of the excitons in the light-emitting layer, thereby being able to improve the luminous efficiency of the device. The exciton-blocking layer may be inserted on any of the anode side and the cathode side of the adjacent light-emitting layer, and may also be inserted simultaneously on both sides.

The heterocyclic compound of the present invention may be used as a material for the exciton-blocking layer. However, as other materials therefor, there are given, for example, 1,3-dicarbazolylbenzene (mCP) and bis(2-methyl-8-quinolinolato)-4-phenylphenolatoaluminum(III) (BAlq)

—Hole-Transporting Layer—

The hole-transporting layer is formed of a hole-transporting material having a function of transporting holes, and a single hole-transporting layer or a plurality of hole-transporting layers may be formed.

The hole-transporting material has a hole-injecting property or a hole-transporting property or has an electron-blocking property, and any of an organic material and an inorganic material may be used as the hole-transporting material. It is preferred to use the material for an organic electroluminescent device of the present invention as a known hole-transporting material that may be used. However, any compound selected from conventionally known compounds may be used. As the known hole-transporting material that may be used, there may be used, for example, a triazole derivative, an oxadiazole derivative, an imidazole derivative, a polyarylalkane derivative, a pyrazoline derivative and a pyrazolone derivative, a phenylenediamine derivative, an arylamine derivative, an amino-substituted chalcone derivative, an oxazole derivative, a styrylanthracene derivative, a fluorenone derivative, a hydrazone derivative, a stilbene derivative, a silazane derivative, an aniline-based copolymer, and a conductive high-molecular weight oligomer, a thiophene oligomer, a porphyrin compound, an aromatic tertiary amine compound, a carbazole derivative, and a styrylamine compound. However, the known hole-transporting material that may be used is not particularly limited thereto.

—Electron-Transporting Layer—

The electron-transporting layer is formed of a material having a function of transporting electrons, and a single electron-transporting layer or a plurality of electron-transporting layers may be formed.

An electron-transporting material (which also serves as a hole-blocking material in some cases) only needs to have a function of transferring electrons injected from the cathode into the light-emitting layer. It is preferred to use the heterocyclic compound of the present invention for the electron-transporting layer. However, any compound selected from conventionally known compounds may be used. Examples thereof include a nitro-substituted fluorene derivative, a diphenylquinone derivative, a thiopyran dioxide derivative, a carbodiimide, a fluorenylidenemethane derivative, anthraquinodimethane and anthrone derivatives, and an oxadiazole derivative. Further, a thiadiazole derivative prepared by substituting an oxygen atom on an oxadiazole ring with a sulfur atom in the oxadiazole derivative or a quinoxaline derivative that has a quinoxaline ring known as an electron withdrawing group may be used as the electron-transporting material. Further, a polymer material in which any such material is introduced in a polymer chain or is used as a polymer main chain may be used.

### EXAMPLES

Now, the present invention is described in more detail by way of Examples. It should be appreciated that the present invention is not limited to Examples below and may be carried out in various forms as long as the various forms do not deviate from the gist of the present invention. The number of each compound corresponds to the number given to the chemical formula.

### Example 1

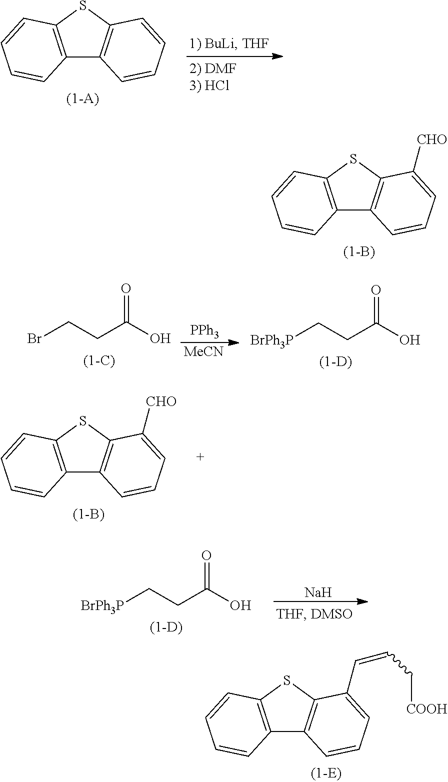

In a stream of a nitrogen gas, dibenzothiophene (1-A) (109 mmol, 20.0 g) and dehydrated THF (100 mL) were added to a 1,000-milliliter reactor, and were stirred at 0° C. for 30 min. A 2 N solution of BuLi in hexane (60 mL, 156 mmol) was dropped to the mixture. After the completion of the dropping, the mixture was heated to reflux for 6 hr. After the resultant had been cooled to room temperature, dehydrated DMF (20 mL, 160 mmol) was dropped to the resultant, and then the mixture was stirred overnight at room temperature. The reaction mixture was poured into 6 N hydrochloric acid (500 mL), and the whole was extracted with acetic acid. The organic layer was washed with water and dried, followed by column chromatography. Thus, 8.0 g of a compound (1-B) was obtained.

In a stream of a nitrogen gas, 3-bromopropionic acid (1-C) (169 mmol, 25 g), triphenylphosphine (196 mmol, 51.42 g), and dehydrated acetonitrile (70 mL) were added to a 500-milliliter reactor. After the completion of the addition, the mixture was stirred under heating to reflux for 5 hr. After having been left standing to cool to room temperature, the reaction liquid was concentrated. The produced solid was washed with ethyl acetate to provide 65.2 g of a wittig-salt (1-D).

In a stream of a nitrogen gas, the compound (1-B) (37.7 mmol, 8.0 g), the wittig-salt (1-D) (3,377 mmol, 1,402 g), dehydrated THF (75 mL), and dehydrated DMSO (75 mL) were added to a 500-milliliter reactor, and were stirred at 27° C. (water bath) for 30 min. 60% sodium hydride (112.1 mmol, 3.5 g) was gradually poured into the mixture, and the whole was stirred for 6 hr. The reaction mixture was poured into a 2 N aqueous solution of sodium hydroxide, and the whole was washed with ethyl acetate. Further, the ethyl acetate layer was extracted with a 2 N aqueous solution of sodium hydroxide. The aqueous layers were combined with each other, and 6 N hydrochloric acid was added to the resultant to adjust its pH to 1, followed by extraction with ethyl acetate. The organic layer was washed with water and the solvent was distilled off Thus, 9.6 g of a compound (1-E) was obtained.

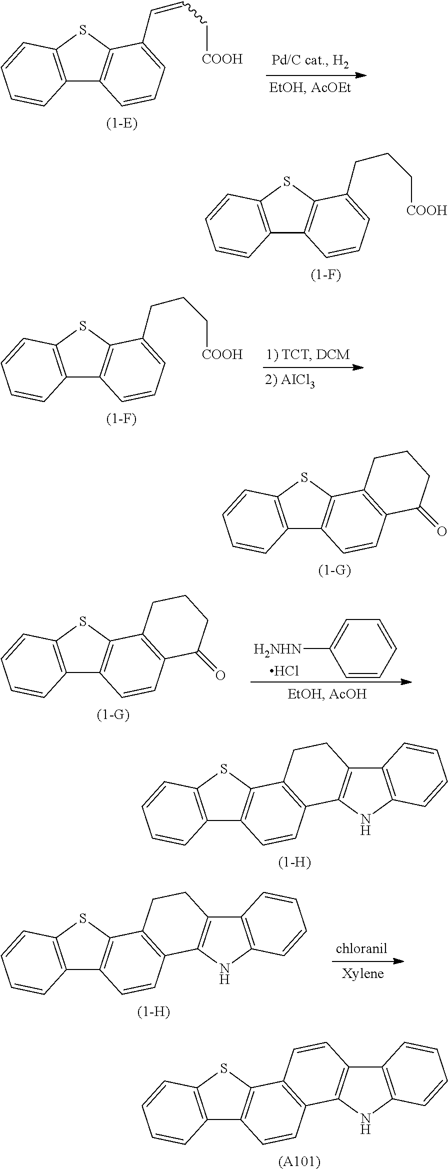

In a stream of a nitrogen gas, the compound (1-E) (35 mmol, 9.4 g), dehydrated ethanol (50 mL), dehydrated ethyl acetate (50 mL), and 10% Pd/C (0.5 g) were added to a 300-milliliter reactor, and nitrogen replacement was performed for 10 min. A hydrogen gas was blown into the solvent by using a hydrogen bubbling apparatus at room temperature for 10 hr. Further, 10% Pd/C (0.5 g) was added to the reactor, and hydrogen was blown thereinto for 9 hr. After the completion of the reaction, the catalyst was separated by filtration, and then the solvent was distilled off. Thus, 8.8 g of a compound (1-F) was obtained.

In a stream of a nitrogen gas, the compound (1-F) (32.6 mmol, 8.8 g), 2,4,6-trichloro-1,3,5-triazine (65.1 mmol, 12.0 g), and dehydrated dichloromethane (50 mL) were added to a 200-milliliter reactor, and were stirred at room temperature for 5 min. After that, dehydrated pyridine (97.7 mmol, 7.7 g) was slowly poured into the mixture at room temperature, and the whole was stirred for 8 hr. Subsequently, aluminum chloride (65.1 mmol, 8.7 g) was slowly added to the resultant at room temperature, and the mixture was stirred for 4 hr. After the completion of the reaction, the resultant was poured into 1 N HCl, and the mixture was extracted with chloroform. The organic layer was washed with water and dried, and the solvent was distilled off, followed by column chromatography. Thus, 3.3 g of a compound (1-G) was obtained.

In a stream of a nitrogen gas, the compound (1-G) (6.0 mmol, 2.5 g) and a solution (5 mL) of phenylhydrazine hydrochloride (12 mmol, 1.7 g) in dehydrated ethanol were added to a 50-milliliter reactor, and were stirred at room temperature for 5 min. After that, glacial acetic acid (4.8 mmol, 0.3 g) was poured into the mixture, and the whole was stirred at 90° C. for 4.5 hr. After the completion of the reaction, the produced precipitate was separated by filtration, and was washed with ethanol and water. After that, the precipitate was further washed with dichloromethane to provide 2.7 g of a compound (1-H).

Under a nitrogen gas atmosphere, the compound (1-H) (10.3 mmol, 3.4 g), chloranil (14.4 mmol, 3.5 g), and xylene (150 mL) were added to a 300-milliliter recovery flask, and were heated to reflux for 6 hr. After the completion of the reaction, the reaction mixture was cooled to room temperature, and the precipitated solid was separated by filtration. The solid separated by filtration was washed with toluene and dichloromethane to provide 3.0 g of a compound (A101).

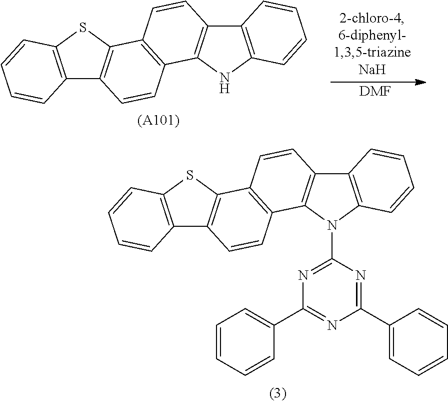

In a stream of a nitrogen gas, 0.33 g (0.0083 mol) of 60.8% sodium hydride and 4 g of dehydrated N,N-dimethylformamide (DMF) were added and stirred. A solution obtained by dissolving 2.0 g (0.0063 mol) of the (A101) obtained in the foregoing in 4 g of DMF was dropped to the mixture over 5 min, and then the whole was stirred for 1 hr. After that, a solution obtained by dissolving 1.69 g (0.0063 mol) of 2-chloro-4,6-diphenyl-1,3,5-triazine in 4 g of DMF was dropped to the resultant over 5 min, and then the mixture was stirred for 7 hr. After that, 2.0 g of distilled water was added to the resultant, and 30.0 g of methanol was added thereto. The precipitated crystal was separated by filtration. The crystal was dried under reduced pressure, and was then purified by column chromatography to provide 2.61 g (0.0047 mol, yield: 75.0%) of a compound (3) as white powder. The APCI-TOFMS of the compound showed a [M+H]⁺ peak at an m/z of 555.

Compounds (4), (5), (10), (13), and (18) were synthesized in conformity with the synthesis example and the synthesis method described herein.

In addition, an organic EL device was produced by using the compound (3), (4), (5), (10), (13), (18), or CBP, or the heterocyclic compound (H-1) or (H-2).

### Example 2

Each thin film was laminated by a vacuum deposition method at a degree of vacuum of 2.0×10⁻⁵ Pa on a glass substrate on which an anode formed of indium tin oxide (ITO) having a thickness of 150 nm had been formed. First, copper phthalocyanine (CuPC) was formed into a layer having a thickness of 20 nm to serve as a hole-injecting layer on the ITO. Next, α-NPD was formed into a layer having a thickness of 40 nm to serve as a hole-transporting layer. Next, the compound (3) serving as a host material for a light-emitting layer and Ir(ppy)₃ serving as a dopant were co-deposited from different deposition sources onto the hole-transporting layer to form a light-emitting layer having a thickness of 35 nm. The concentration of Ir(ppy)₃ was 7.0%. Next, Alq₃ was formed into a layer having a thickness of 40 nm to serve as an electron-transporting layer. Further, lithium fluoride (LiF) was formed into a layer having a thickness of 0.5 nm to serve as an electron-injecting layer on the electron-transporting layer. Finally, aluminum (Al) was formed into a layer having a thickness of 170 nm to serve as an electrode on the electron-injecting layer. Thus, an organic EL device was produced.

An external power source was connected to the resultant organic EL device to apply a DC voltage to the device. As a result, it was confirmed that the device had such light-emitting characteristics as shown in Table 1. The columns “luminance”, “voltage”, and “luminous efficiency” in Table 1 show values at the time of driving at 10 mA/cm² (initial characteristics). The maximum wavelength of the emission spectrum of the device was 520 nm, and hence the acquisition of light emission from Ir(ppy)₃ was found.

### Examples 3 to 7

Organic EL devices were each produced in the same manner as in Example 2 except that the compound (4), (5), (10), (13), or (18) was used as a host material for the light-emitting layer in Example 2 instead of the compound (3).

### Example 8

An organic EL device was produced in the same manner as in Example 2 except that the compound (3) and CEP were co-deposited at a ratio (weight ratio) of 30:70 as host materials for the light-emitting layer in Example 2 instead of the compound (3).

### Example 9

An organic EL device was produced in the same manner as in Example 2 except that the compound (3) and CBP were co-deposited at a ratio of 40:60 as host materials for the light-emitting layer in Example 2 instead of the compound (3).

### Example 10

An organic EL device was produced in the same manner as in Example 2 except that the compound (18) and the compound (5) were co-deposited at a ratio of 40:60 as host materials for the light-emitting layer in Example 2 instead of the compound (3).

### Example 11

An organic EL device was produced in the same manner as in Example 2 except that the compound (18) and the compound (5) were co-deposited at a ratio of 50:50 as host materials for the light-emitting layer in Example 2 instead of the compound (3).

### Comparative Example 1

An organic EL device was produced in the same manner as in Example 2 except that CBP was used as a host material for the light-emitting layer in Example 2 instead of the compound (3).

### Comparative Example 2

An organic EL device was produced in the same manner as in Example 2 except that the heterocyclic compound (H-1) was used as a host material for the light-emitting layer in Example 2 instead of the compound (3).

### Comparative Example 3

An organic EL device was produced in the same manner as in Example 2 except that the heterocyclic compound (H-2) was used as a host material for the light-emitting layer in Example 2 instead of the compound (3).

The organic EL devices obtained in Examples 3 to 11 and Comparative Examples 1 to 3 were evaluated in the same manner as in Example 2. As a result, it was confirmed that the devices had such light-emitting characteristics as shown in Table 1. The maximum wavelength of each of the emission spectra of the organic EL devices obtained in Examples 3 to 11 and Comparative Examples 1 to 3 was 530 nm, and hence the acquisition of light emission from Ir(ppy)₃ was identified.

TABLE 1

| | | | | Visual luminous |
|---|---|---|---|---|
| | Host material | Luminance | Voltage | efficiency |
| | compound | (cd/m²) | (V) | (lm/W) |
| Example 2 | (3) | 2,450 | 5.2 | 14.8 |
| Example 3 | (4) | 2,320 | 5.8 | 12.6 |
| Example 4 | (5) | 2,470 | 5.7 | 13.6 |
| Example 5 | (10) | 2,610 | 5.1 | 16.1 |
| Example 6 | (13) | 2,560 | 5.9 | 15.8 |
| Example 7 | (18) | 2,430 | 5.2 | 14.7 |
| Example 8 | (3) + CBP | 2,730 | 5.7 | 15.9 |
| | (30:70) | | | |
| Example 9 | (3) + CBP | 2,740 | 5.4 | 15.7 |
| | (40:60) | | | |
| Example 10 | (18) + (5) | 2,660 | 5.8 | 14.4 |
| | (40:60) | | | |
| Example 11 | (18) + (5) | 2,590 | 5.5 | 14.8 |
| | (50:50) | | | |
| Comparative | CBP | 2,180 | 8.2 | 8.3 |
| Example 1 | | | | |
| Comparative | (H-1) | 2,205 | 6.9 | 10.0 |
| Example 2 | | | | |
| Comparative | (H-2) | 2,210 | 6.8 | 10.2 |
| Example 3 | | | | |

### INDUSTRIAL APPLICABILITY

The material for an organic electroluminescent device of the present invention can be suitably utilized particularly in a thin film-type display device, such as a flat panel display, because when the material is used in an organic EL device, a reduction in driving voltage of the device and high luminous efficiency can be achieved, and the device has a long driving life and durability at a practical level.

### REFERENCE SIGNS LIST

1 substrate, 2 anode, 3 hole-injecting layer, 4 hole-transporting layer, 5 light-emitting layer, 6 electron-transporting layer, 7 cathode

1. A material for an organic electroluminescent device, comprising a heterocyclic compound represented by the general formula (1): 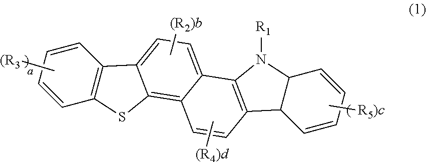
where:
R₁ represents an alkyl group having 1 to 12 carbon atoms, an alkoxy group having 1 to 12 carbon atoms, a substituted or unsubstituted aromatic hydrocarbon group having 6 to 30 carbon atoms, a substituted or unsubstituted aromatic heterocyclic group having 3 to 22 carbon atoms, or a substituted or unsubstituted linked aromatic group obtained by linking 2 to 6 aromatic rings of the aromatic groups;
R₂ to R₅ each independently represent an alkyl group having 1 to 12 carbon atoms, an alkoxy group having 1 to 12 carbon atoms, a substituted or unsubstituted aromatic hydrocarbon group having 6 to 30 carbon atoms, a substituted or unsubstituted aromatic heterocyclic group having 3 to 22 carbon atoms, the group containing only oxygen or sulfur as a heteroatom, or a substituted or unsubstituted linked aromatic group obtained by linking 2 to 6 aromatic rings of the aromatic groups; and
a, b, c, and d each independently represent an integer of from 0 to 2.

2. An organic electroluminescent device having a structure in which an anode, organic layers, and a cathode are laminated on a substrate, at least one layer of the organic layers comprising an organic layer containing the material for an organic electroluminescent device of claim 1.

3. An organic electroluminescent device according to claim 2, wherein the organic layer containing the material for an organic electroluminescent device comprises at least one layer selected from the group consisting of a light-emitting layer, an electron-transporting layer, and a hole-blocking layer.

4. An organic electroluminescent device according to claim 2, wherein the organic layer containing the material for an organic electroluminescent device comprises a light-emitting layer.

5. An organic electroluminescent device according to claim 4, wherein the light-emitting layer contains a light-emitting dopant and a host material.

6. An organic electroluminescent device according to claim 5, wherein the light-emitting layer contains the host material and a phosphorescent light-emitting dopant serving as the light-emitting dopant, and the material for an organic electroluminescent device comprises the host material.

7. An organic electroluminescent device according to claim 5, wherein the light-emitting layer contains the host material and a fluorescent light-emitting dopant serving as the light-emitting dopant, and the material for an organic electroluminescent device comprises the host material.

8. An organic electroluminescent device according to claim 5, wherein the light-emitting layer contains the host material and a delayed fluorescent light-emitting dopant serving as the light-emitting dopant, and the material for an organic electroluminescent device comprises the host material.

9. An organic electroluminescent device according to claim 5, wherein the light-emitting layer contains the host material and a delayed fluorescent light-emitting dopant serving as the light-emitting dopant, and the material for an organic electroluminescent device comprises the delayed fluorescent light-emitting dopant.

10. An organic electroluminescent device according to claim 5, wherein the light-emitting layer contains the host material and a fluorescent light-emitting dopant serving as the light-emitting dopant, and the material for an organic electroluminescent device comprises the fluorescent light-emitting dopant.

11. An organic electroluminescent device according to claim 5, wherein the light-emitting layer contains two or more kinds of host materials and one or more kinds of light-emitting dopants, and at least one kind of the host materials comprises the material for an organic electroluminescent device.

12. An organic electroluminescent device according to claim 5, wherein the light-emitting layer contains two or more kinds of host materials and one or more kinds of light-emitting dopants, and at least one kind of the light-emitting dopants comprises the material for an organic electroluminescent device.
